(19) United States
(12) Patent Application Publication
(10) Pub. No.: US 2026/0352033 A1
(43) Pub. Date: Nov. 5, 2026

(54) SYSTEMS AND METHODS FOR WIRELESS POWER BEAMING USING A RELAY ANTENNA

(71) Applicant: EMROD LIMITED, Auckland (NZ)

(72) Inventor: Andrew Raymond SIMPKIN, Auckland (NZ)

(73) Assignee: EMROD LIMITED, Auckland (NZ)

(21) Appl. No.: 19/487,817

(22) PCT Filed: May 30, 2024
(86) PCT No.: PCT/IB2024/055241

§ 371 Date: Nov. 25, 2025

Related U.S. Application Data
(60) Provisional application No. 63/505,281, filed on May 31, 2023.

(51) Int. Cl. H02J 50/50; H01Q 3/36; H02J 50/27; H04B 7/155

(52) U.S. Cl. CPC H02J 50/50; H01Q 3/36; H02J 50/27; H04B 7/15528

(57) ABSTRACT

Systems and methods for relaying a wireless power beam using a relay antenna having a plurality of phase shifters is provided. The relay antenna can include a plurality of phase shifters, where each phase shifter includes a reconfigurable phase shift setting. A first emitter positioned at a first location relative to the relay antenna can to transmit a first pilot beam, a second emitter positioned at a second location relative to the relay antenna can transmit a second pilot beam, and the reconfigurable phase shift setting can be set based on a difference in phase between the first pilot beam and the second pilot beam as received by each phase shifter of the relay antenna.

### FIELD OF THE INVENTION

The present invention relates to the field of wireless power transfer, in particular to relaying a wireless power beam using a relay antenna having phase shifters.

### BACKGROUND

Currently, certain wireless power transfer applications, for example, to Earth from space-born microwave antennas and solar arrays and/or terrestrial power beaming are conceptual technologies that have yet to be practically implemented due to, for example, limitations on the technology that exists to bring these concepts to implementation.

### SUMMARY OF THE INVENTION

Some of the advantages of the invention can include one or more of the following: an ability to wirelessly relay power with high beam collection efficiency between locations that do not otherwise have a line-of-sight connection; an ability to automatically maintain a focused and correctly orientated wireless power beam onto its intended target in real-time even for moving targets; an ability to minimize the aperture size of transmitting, receiving and relay antennas whilst maintaining high beam collection efficiencies when wirelessly beaming power over long distances; an ability to automatically correct for phase aberrations that might occur in the medium through which the power beam propagates (such as atmospheric or ionospheric effects), in real-time, particularly when the frequency of the pilot beam is the same as that of the power beam.

In one aspect, the invention involves a method of relaying a wireless power beam using a relay antenna having a plurality of phase shifters. The method involves receiving by the relay antenna, from a first emitter positioned on a transmit antenna at a first location relative to the relay antenna, a first pilot beam directed towards the relay antenna. The method involves receiving by the relay antenna, from a second emitter positioned on a receive antenna at a second location relative to the relay antenna, a second pilot beam. The method involves determining, by the relay antenna, a phase for each phase shifter of the plurality of phase shifters based on a difference in phase between the first pilot beam and the second pilot beam as received by each phase shifter of the relay antenna. The method involves setting, by the relay antenna, each phase shifter to operate with the respective determined phase to relay a wireless power beam from the transmit antenna to the receive antenna.

In another aspect, the method involves receiving by the relay antenna, from the first emitter positioned on the transmit antenna at a first location relative to the relay antenna, a first update pilot beam directed towards the relay antenna, receiving by the relay antenna, from the second emitter positioned on the receive antenna at a second location relative to the relay antenna, a second update pilot beam, determining an updated phase for each phase shifter of the plurality of phase shifters based on an updated difference in phase between the first update pilot beam and the second update pilot beam as received by each phase shifter of the relay antenna, and setting, by the relay antenna, each phase shifter to operate with the respective updated phase.

In another aspect, the invention includes a relay antenna for a dual pilot beam for wireless power beaming. The relay antenna includes a plurality of phase shifters. Each phase shifter includes a phase shifting element having a first input for receiving a first pilot beam and a second input for receiving a second pilot beam. Each phase shifter also includes an I Q demodulator to determine a phase difference between the first pilot beam and the second pilot beam and setting a phase for the particular phase shifter based on the phase difference.

In some embodiments, each phase shifters in the plurality of phase shifters are positioned relative to one another such that there is half a wavelength distance between antennas of respective orthogonally adjacent phase shifters. In some embodiments, a number of the plurality of phase shifter is based on a wavelength of the first pilot beam or the second pilot beam.

In another aspect, the invention involves a system for a dual pilot beam relay antenna for wireless power beaming. The system includes a relay antenna including a plurality of phase shifters. Each phase shifter includes a reconfigurable phase shift setting. The system also includes a first emitter positioned at a first location relative to the relay antenna, the first emitter to transmit a first pilot beam. The system also includes a second emitter positioned at a second location relative to the relay antenna, the second emitter to transmit a second pilot beam, wherein the reconfigurable phase shift setting is set based on a difference in phase between the first pilot beam and the second pilot beam as received by each phase shifter of the relay antenna.

In some embodiments, each of the phase shifters comprises a phase shifting element and an I Q demodulator to determine the phase difference between the first pilot beam and the second pilot beam. In some embodiments, the first emitter transmits the first pilot bean towards a first input of the relay antenna and the second emitter transmits the second pilot beam towards a second input of the relay antenna.

In some embodiments, the phase shifters in the plurality of phase shifters are positioned relative to one another such that there is half a wavelength between antennas of each of the plurality of phase shifters. In some embodiments, a number of the plurality of phase shifter is based on a wavelength of the first pilot beam or the second pilot beam.

In some embodiments of the invention, the frequency of the pilot beam is the same as the frequency of the wireless power beam.

### BRIEF DESCRIPTION OF THE DRAWINGS

Non-limiting examples of embodiments of the disclosure are described below with reference to figures attached hereto that are listed following this paragraph. Dimensions of features shown in the figures are chosen for convenience and clarity of presentation and are not necessarily shown to scale.

The subject matter regarded as the invention is particularly pointed out and distinctly claimed in the concluding portion of the specification. The invention, however, both as to organization and method of operation, together with objects, features and advantages thereof, can be understood by reference to the following detailed description when read with the accompanied drawings. Embodiments of the invention are illustrated by way of example and not limitation in the figures of the accompanying drawings, in which like reference numerals indicate corresponding, analogous or similar elements, and in which:

FIG. 1 is a diagram of a system for a dual pilot beam relay antenna for wireless power beaming, according to some embodiments of the invention.

FIG. 2 is a diagram of a dual pilot beam relay antenna for wireless power beaming, according to some embodiments of the invention.

FIG. 3 is a diagram of a system for a dual pilot beam relay antenna for wireless power beaming, according to some embodiments of the invention.

FIG. 4 is a diagram of a individual phase shifter of a dual pilot beam relay antenna, according to some embodiments of the invention.

FIG. 5 is a flowchart for a method for relaying a wireless power beam using a relay antenna having a plurality of phase shifters, according to some embodiments of the invention.

It will be appreciated that for simplicity and clarity of illustration, elements shown in the figures have not necessarily been drawn accurately or to scale. For example, the dimensions of some of the elements can be exaggerated relative to other elements for clarity, or several physical components can be included in one functional block or element.

### DETAILED DESCRIPTION

In the following detailed description, numerous specific details are set forth in order to provide a thorough understanding of the invention. However, it will be understood by those skilled in the art that the invention can be practiced without these specific details. In other instances, well-known methods, procedures, and components, modules, units and/or circuits have not been described in detail so as not to obscure the invention.

Generally, in some wireless power beaming applications, arrays of phase shifting elements may be used to create a relay antenna array for receiving a focused power beam and transmitting it onward as a refocused power beam. A phase difference can be determined to introduce to a power signal at each phase shifting element in order to, for example, produce a focused power beam at a destination of the power signal.

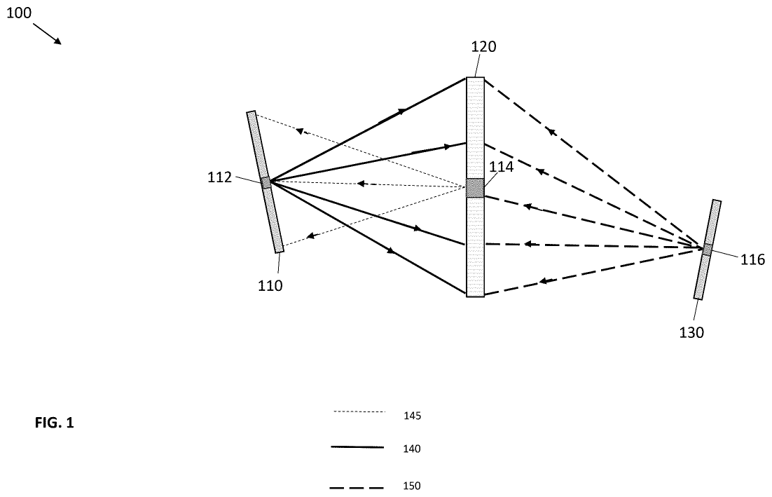

FIG. 1 shows a diagram of a system 100 for a dual pilot beam relay antenna for wireless power beaming, according to some embodiments of the invention. The system 100 includes a transmitting phased array antenna 110, a relay antenna 120, and receiving array antenna 130.

The transmitting phased array antenna 110 includes a centrally located pilot beam emitter 112. The receiving array antenna 130 includes a centrally located pilot beam emitter 116. The relay antenna 120 includes an array of phase-shifting antenna elements and a centrally located pilot beam emitter 114. The relay antenna 120 can be positioned in between the transmitting phased array antenna 110 and the receiving array antenna 130.

During operation, pilot beams can be transmitted from each of the centrally located pilot beam emitter 112, the centrally located pilot beam emitter 114, and the centrally located pilot beam emitter 116 with a frequency that is the same as a power beam to be transmitted from the transmitting phased array antenna 110 through the relay antenna 120 to the receiving array antenna 130. As shown, the transmitting phased array antenna 110 can transmit pilot beam emitter rays 140 from the centrally located pilot beam emitter 112 of the transmitting phased array antenna 110 to the relay antenna 120; the centrally located pilot beam emitter 114 can transmit pilot beam emitter rays 145 from the centrally located pilot beam emitter 114 of the relay antenna 120, and the a centrally located pilot beam emitter 116 can transmit pilot beam emitter rays 150 from the centrally located pilot beam emitter 116 of the receiving array antenna 130. The pilot beam emitter 114 is typically not used when the relay antenna 120 is behaving solely as a relay between a transmitter and receiver. In various embodiments, multiple relay antennas can be cascaded such that one relay becomes an intended target of an incoming power beam or a transmitter to another relay. Therefore, including a pilot beam emitter in the relay antenna can allow for relay antenna to operate in cascaded scenario with multiple relays.

The centrally located pilot beam emitter 112, the centrally located pilot beam emitter 114, and the centrally located pilot beam emitter 114 can be a small antenna (e.g., less than 10 wavelengths across and for which the radiation pattern received by the intended target is in the radiating far-field region) that radiates a low-power (e.g., at least three orders of magnitude lower than the power beam being relayed) spherical wavefront that is intercepted by an adjacent array aperture. The low-power spherical wavefront can focus an incoming beam onto its respective target aperture.

In some embodiments of the invention, a pilot beam maybe one for which a radiated field at the target location has a spherical wavefront that emanates from the centrally located emitter. This means that the target aperture is within the radiating far-field region of the pilot beam emitter antenna. This in turn can require that the pilot beam antenna be sufficiently small for this condition to be satisfied. The far-field region can be defined as being at a distance R greater than or equal to 2D²/λ where lambda (λ) is the wavelength and D the diameter of the pilot beam antenna.

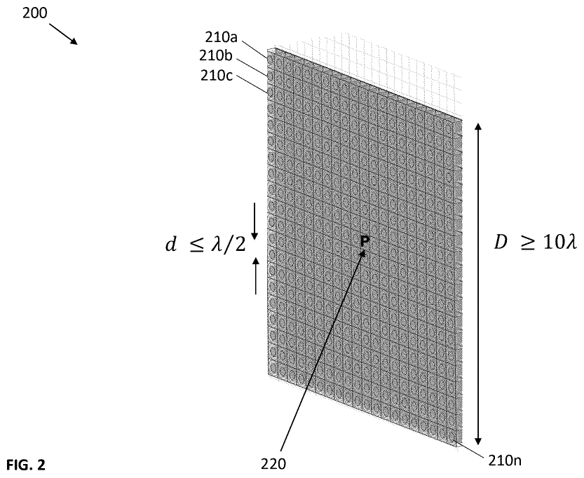

FIG. 2 is a diagram of a relay antenna 200 (e.g., dual pilot beam relay antenna) for wireless power beaming, according to some embodiments of the invention. The dual pilot beam relay antenna can include an array of individual phase shifting antenna elements 210a, 210b, 210c, . . . , 210n, generally 210 and a centrally located pilot beam emitter 220. The size D of the dual pilot beam relay antenna 200 can be at least 10 wavelengths (e.g., operating wavelengths) across. The spacing of the elements across the face of the array, d, can be one-half (½) of the operating wavelength or less.

In some embodiments, a number of phase shifting antenna elements 210 depends upon the aperture size relative to the wavelength of operation. For example, to provide a focused and electronically steerable beam that is free from grating lobes for any steering angle, the element spacing can be one half of a free-space wavelength or less. In some embodiments, a number of phase shifting antenna elements 210 is equal to 4 times the overall antenna aperture area divided by the wavelength squared when the element spacing is equal to the maximum of one half of a free-space wavelength for grating-lobe free operating.

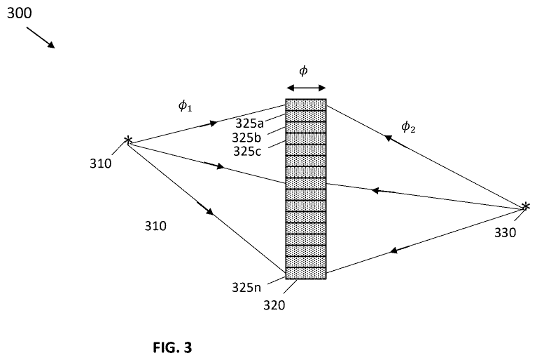

FIG. 3 is a diagram of a system 300 for a dual pilot beam relay antenna for wireless power beaming, according to some embodiments of the invention. The system 300 includes a first pilot beam emitter 310, a relay antenna 320, and a second pilot beam emitter 330.

The relay antenna 320 can be positioned in between the first emitter 310 and the second emitter 330. The relay antenna 320 can include a plurality of phase shifter elements 325a, 325b, 325c, . . . 325n, generally 325, including an antenna and a phase shifter in each array element as shown above in FIG. 2. The phase shifters can have a reconfigurable phase shift setting, such that the phase shift provided by each of the phase shifters can change.

In various embodiments, multiple relays are cascaded, such that each relay antenna has its own pilot beam emitter.

During operation, the first emitter 310 can transmit a first pilot beam to the relay antenna and the second emitter 330 can transmit a second pilot beam towards to the relay antenna 320. The relay antenna 320 can configure phase shift settings of each of the phase shifting elements based on a difference in phase between the first pilot beam and the second pilot beam. In this manner, the relay antenna 320 can be set (e.g., tuned) for a particular transmitting antenna and destination antenna, and the relay antenna 320 can be used for different power beams, transmitting antennas and destination antennas requiring a different phase then they were originally set too.

The first pilot beam (e.g., source pilot beam) can have a phase φ₁ at an input port to each phase shifter. The second pilot beam (e.g., destination pilot beam) can have a phase φ₂ at an output port of each of the phase shifter. Each phase shifter can introduce a phase shift φ between the input and output ports. The phase shift can be adjusted to any value between 0 and 2π radians via electronic circuits and/or mechanical devices, as is known in the art.

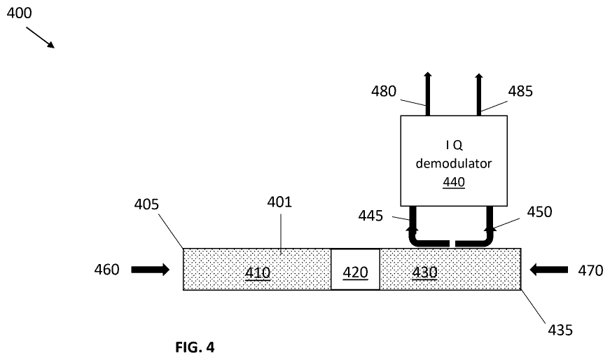

In order to re-focus an incoming beam from a transmitting antenna onto a receiving antenna via a relay array, a required phase shift, o, for each and every element of the relay array that equalizes the path length from pilot beam emitter #1, through the phase shifter in the relay and to the pilot beam emitter location #2 at the receiver can be determined. The phase shift can determined by using an IQ demodulator as described below in FIG. 4.

FIG. 4 is a diagram of a individual phase shifter 400 of a dual pilot beam relay antenna, according to some embodiments of the invention. The individual phase shifter 400 can include a phase shifting element 401 and an IQ demodulator 440.

The phase shifting element 401 can be coupled to the IQ demodulator 440.

The phase shifting element 401 can include a first aperture 405, a first waveguide coupled input port 410, an adjustable phase shifter element 420, a second waveguide coupled input port 430, and a second aperture 435.

The IQ demodulator 440 can be coupled to the phase shifting element 401 via a dual directional coupler having two arms, a first arm 445 and a second arm 450. The first arm 445 of the dual directional coupler can couple a signal (e.g., an electromagnetic wave) received by the phase shifting element 401 from the second pilot beam and the second arm 450 of the dual directional coupler can couple a signal received by the phase shifting element 401 from the first pilot beam. In some embodiments, the first arm 445 couples a signal received by the phase shifting element 401 from the first pilot beam and the second arm couples a signal received by the phase shifting element from the second pilot beam.

During operation, a first electromagnetic wave 460 from a source pilot beam (e.g., first emitter 310 as described above with respect to FIG. 3) can be incident upon the first aperture 405, and propagates through the waveguide 410 and through the adjustable phase shifter element 420, to the second arm 450 of the IQ demodulator. A second electromagnetic wave 470 from a source pilot beam (e.g., first emitter 310 as described above with respect to FIG. 3) can be incident upon the second aperture 405, and propagate through the waveguide 410 through the phase an adjustable phase shifter element 420, to the second arm 450 of the IQ demodulator 440.

The first electromagnetic wave 460 and the second electromagnetic wave 470 propagate in opposite directions through the phase shifting element 401 through the phase shifting element 401 and can be received by the IQ demodulator 440 through the first arm 445 and the second arm 450 of the dual directional coupler such that the first electromagnetic wave 460 and the second electromagnetic wave 470 can be distinguished and a phase setting determined for the phase shifting element 401.

The phase to set each phase shifting element 401 can be determined based on I output 480 and Q output 485.

The I output 480 and Q output 485 from the IQ demodulator 440 can be expressed as follows, where the amplitude has been removed through normalization with respect to \sqrt{I²+Q²}:

I=cos (φ₁+φ−φ₂) EQN. 1

Q=sin(φ₁+φ−φ₂) EQN. 2

where φ₁ is the phase of the first electromagnetic wave 460, φ₂ is the phase of the second electromagnetic wave 470 and φ is the phase delay introduced by an individual element of the relay antenna and its associated adjustable phase shifter 401. From the above expressions in EQN. 1 it can be seen that the phase difference between the two signals enters the argument of the trigonometric functions. For the purposes of beam focusing with the dual pilot beam relay antenna, the total phase delay between the sources of the two pilot beams (e.g., the first pilot beam 145 and the second pilot beam 150) can be the same for all relay elements.

Total phase delay between the sources of the two pilot beams as the same for all relay elements can be expressed as follows:

φ=φ₁+φ₂+φ=constant EQN. 3
where in Φ is the total phase delay for each phase shifting element 401 of the dual pilot beam relay antenna. Therefore, the focusing condition expressed in EQN. 3 involves a phase sum. The phase sum can be determined from measurements of a phase difference between the two pilot beam (e.g., as obtained via the IQ demodulator 440), for example, as follows:

The I and Q parameters can be with the constant phase delay as follows:

Ĩ=cos(Φ)=cos(φ₁+φ₂+φ) EQN. 4

\tilde{Q}=sin(Φ)=sin(φ₁+φ₂+φ) EQN. 5

In EQN. 4 and EQN. 5, the phase sum appears in the argument of the trigonometric functions. What follows is a method that can involve the I and Q values determined by measurement in EQN. 1 and EQN. 2 and their transformation into EQN. 4 and EQN. 5 which can be used to inform the phase shifter setting of each phase shifting element 401 to achieve a desired relay focusing condition (e.g., cause a beam transmitting from the source transmitter to be relayed to the destination transmitter, where the source transmitter and the destination transmitter can each include the first emitter and the second emitter that transmits the first and second pilot beam).

By expanding EQN. 1 and EQN. 2 using well-known multiple angle formulas for the trig functions can result in the following:

I=cos(φ₁+φ−φ₂)=cos(φ₁+φ)cos(φ₂)+sin(φ₁+φ)sin(φ₂) EQN. 6

Q=sin(φ₁+φ−φ₂)=sin(φ₁+φ)cos(φ₂)−cos(φ₁+φ)sin(φ₂) EQN.7

EQN. 6 and EQN. 7 can be represented in a matrix as follows:

$$[ \begin{matrix}I \\ Q\end{matrix} ] = [ \begin{matrix}cos {ϕ}_{2} & sin {ϕ}_{2} \\ - sin {ϕ}_{2} & cos {ϕ}_{2}\end{matrix} ] [ \begin{matrix}cos ( {ϕ}_{1} + ϕ ) \\ sin ( {ϕ}_{1} + ϕ )\end{matrix} ] = [ M ] [ V ] \qquad EQN . 8$$

In EQN. 8 the rotation matrix

$$[ M ] = [ \begin{matrix}cos {ϕ}_{2} & sin {ϕ}_{2} \\ - sin {ϕ}_{2} & cos {ϕ}_{2}\end{matrix} ]$$

operates on the column vector

$$[ V ] = [ \begin{matrix}cos ( {ϕ}_{1} + ϕ ) \\ sin ( {ϕ}_{1} + ϕ )\end{matrix} ] .$$

Similarly, EQN. 4 and EQN. 5 can be expanded as follows:

Ĩ=cos(φ₁+φ+φ₂)=cos(φ₁+φ)cos(φ₂)−sin(φ₁+φ)sin(φ₂) EQN. 9

\tilde{Q}=sin(φ₁+φ+φ₂)=sin(φ₁+φ)cos(φ₂)+cos(φ₁+φ)sin(φ₂)EQN.10

EQN. 9 and EQN. 10 can be represented in a matrix as follows:

$$[ \begin{matrix}\tilde{I} \\ \tilde{Q}\end{matrix} ] = [ \begin{matrix}{cos ϕ}_{2} & - sin {ϕ}_{2} \\ {sin ϕ}_{2} & cos {ϕ}_{2}\end{matrix} ] [ \begin{matrix}cos ( {ϕ}_{1} + ϕ ) \\ sin ( {ϕ}_{1} + ϕ )\end{matrix} ] = {[ M ]}^{- 1} [ V ] \qquad EQN . 11$$

Where in EQN. 9 the inverse of the rotation matrix appears on the right-hand side.

Using EQN. 8 and EQN. 11, the column vector [V] can be eliminated using matrix multiplication by [M] to give:

$$[ M ] [ M ] [ \begin{matrix}\tilde{I} \\ \tilde{Q}\end{matrix} ] = [ \begin{matrix}I \\ Q\end{matrix} ] \qquad EQN . 12$$

The matrix product [M] [M] in EQN. 12 can equate to a rotation by angle 2φ₂ with a rotation matrix given by:

$$[ \begin{matrix}cos {ϕ}_{2} & sin {ϕ}_{2} \\ - sin {ϕ}_{2} & cos {ϕ}_{2}\end{matrix} ] [ \begin{matrix}\tilde{I} \\ \tilde{Q}\end{matrix} ] = [ \begin{matrix}I \\ Q\end{matrix} ] \qquad EQN . 13$$

Returning to the focusing condition expressed in EQN. 3, EQN. 4 and EQN. 5, it follows:

Ĩ=cos(Φ)=cos(constant) EQN. 14

\tilde{Q}=sin(Φ)=sin(constant) EQN. 15

The choice of the constant's value in the EQN. 14 and EQN. 15 can be completely arbitrary as long it is applied to all phase shifting element 401 in the dual pilot beam relay antenna. Therefore, Φ=0 (or any integer number of 2π radians), which can allow obtaining Ĩ=1 and \tilde{Q}=0. Substituting these values EQN. 13 gives:

$$[ \begin{matrix}I \\ Q\end{matrix} ] = [ \begin{matrix}{cos 2ϕ}_{2} \\ - {sin 2ϕ}_{2}\end{matrix} ] \qquad EQN . 16$$

Since the values of I and Q are known from measurement, the phase angle 2φ₂ from EQN. 16 and hence obtain the phase φ₂ associated with the second electromagnetic wave 470.

Returning to EQN. 8 and re-arranging to solve for the column vector [V], the following is obtained:

$${[ M ]}^{- 1} [ \begin{matrix}I \\ Q\end{matrix} ] = [ \begin{matrix}cos {ϕ}_{2} & - sin {ϕ}_{2} \\ sin {ϕ}_{2} & cos {ϕ}_{2}\end{matrix} ] [ \begin{matrix}I \\ Q\end{matrix} ] = [ V ] = [ \begin{matrix}cos ( {ϕ}_{1} + ϕ ) \\ sin ( {ϕ}_{1} + ϕ )\end{matrix} ] = [ \begin{matrix}cos {\tilde{ϕ}}_{2} \\ - sin {\tilde{ϕ}}_{2}\end{matrix} ] \qquad EQN . 17$$

where in EQN. 17, \tilde{φ}₁=φ₁+φ.

With a knowledge of I, Q and φ₂ from the above, EQN. 17 can be used to find the elements of the column vector [V] which can enable the phase angle \tilde{φ}₁ to be determined.

When performing the I, Q measurement with two pilot beams active (e.g., from the source emitter and the destination emitter), the phase shifter setting, φ, can be known for each phase shifting element 401 of the dual pilot beam relay antenna. The phase shifter setting, φ, can be set during a pilot beam calibration (e.g., before use of the dual pilot beam relay antenna for power beam transfer). Labeling φ=φ_{cal}, then the phase angle φ₁ associated with first electromagnetic wave 460 can be found since the sum \tilde{φ}₁+1=φ₁+φ_{cal} is known from EQN. 17.

Thus, to determine the phase shifter setting to achieve equal phase delays across all phase shifting elements of the dual pilot beam relay antenna, EQN. 3 can be returned to and the value of the constant phase term can be set to equal zero as before in obtaining as follows:

φ=φ_{1+φ2}+φ=constant=0 EQN. 18

Obtaining the phase shifter setting φ can be as follows:

φ=−(φ₁+φ₂)=φ_{cal}−(φ₁+φ₂) EQN. 19

Where in EQN. 19, the values of φ_{cal}, [symbol] , and φ₂ can be found as described above.

In this manner, the phase shifter setting φ for each phase shifting element 401 in the dual pilot beam relay antenna can be determined.

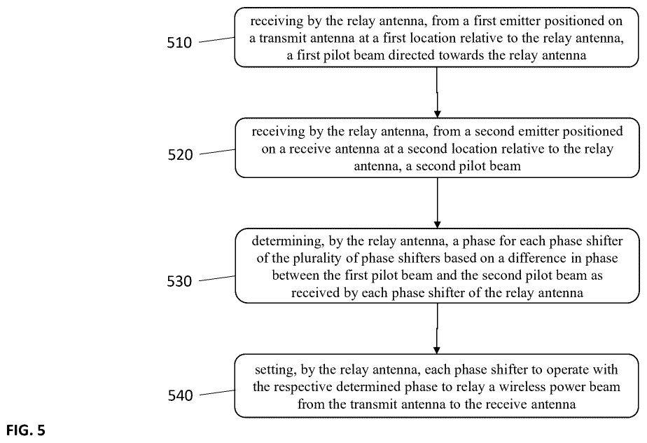

FIG. 5 is a flowchart for a method for relaying a wireless power beam using a relay antenna (e.g., the relay antenna 120 or relay antenna 320 as described above in FIG. 1 and FIG. 3, respectively) having a plurality of phase shifters (e.g., phase shifting elements 325 as described above in FIG. 3), according to some embodiments of the invention.

The method can involve receiving by the relay antenna, from a first emitter (e.g., first emitter 112 as described above in FIG. 1) positioned on a transmit antenna (e.g., transmit antenna 110 as described above in FIG. 1) at a first location relative to the relay antenna (e.g., relay antenna 120 as described above in FIG. 1), a first pilot beam directed towards the relay antenna (Step 510).

The first location can be less than one quarter of the far-field distance. The far-field distance (e.g., Fraunhofer distance) can be equal to 2D²/λ.

The method can involve receiving by the relay antenna, from a second emitter (e.g., first emitter 116 as described above in FIG. 1) positioned on a receive antenna (e.g., transmit antenna 130 as described above in FIG. 1) at a second location relative to the relay antenna (e.g., relay antenna 120 as described above in FIG. 1), a second pilot beam (Step 520).

The method can involve determining, by the relay antenna, a phase (e.g., shifter setting φ as described above) for each phase shifter of the plurality of phase shifters based on a difference in phase between the first pilot beam and the second pilot beam as received by each phase shifter of the relay antenna (Step 530). The difference can be determined based on EQNs 1-19 as described above.

The method can involve setting, by the relay antenna, each phase shifter to operate with the respective determined phase to relay a wireless power beam from the transmit antenna to the receive antenna (Step 540).

Once the relay antenna has a phase set, it can be reset with a different pilot beam, for example, if a different transmitting antenna is used or if the transmitting antenna's emission phase changes.

In some embodiments, the method can involve receiving by the relay antenna, from the first emitter positioned on the transmit antenna at a first location relative to the relay antenna, a first update pilot beam directed towards the relay antenna. The updated pilot beam can be different than the first pilot beam. In some embodiments, the method can involve receiving by the relay antenna, from the second emitter positioned on the receive antenna at a second location relative to the relay antenna, a second update pilot beam. The method can involve determining an updated phase for each phase shifter of the plurality of phase shifters based on an updated difference in phase between the first update pilot beam and the second update pilot beam as received by each phase shifter of the relay antenna. The updated difference can be determined based on EQNs 1-19 as described above. The method can involve setting, by the relay antenna, each phase shifter to operate with the respective updated phase.

As is apparent to one of ordinary skill in the art, the receive antenna array, rectifier module and/or waveguide to transmission line coupler as described above can be coupled to one or more computing elements that is capable of receiving electromagnetic energy, rectified electromagnetic energy and interpret it using various computing elements/devices and/or programs as is known in the art.

One skilled in the art will realize the invention can be embodied in other specific forms without departing from the spirit or essential characteristics thereof. The foregoing embodiments are therefore to be considered in all respects illustrative rather than limiting of the invention described herein. Scope of the invention is thus indicated by the appended claims, rather than by the foregoing description, and all changes that come within the meaning and range of equivalency of the claims are therefore intended to be embraced therein.

In the foregoing detailed description, numerous specific details are set forth in order to provide an understanding of the invention. However, it will be understood by those skilled in the art that the invention can be practiced without these specific details. In other instances, well-known methods, procedures, and components, modules, units and/or circuits have not been described in detail so as not to obscure the invention. Some features or elements described with respect to one embodiment can be combined with features or elements described with respect to other embodiments.

Although embodiments of the invention are not limited in this regard, discussions utilizing terms such as, for example, “processing,” “computing,” “calculating,” “determining,” “establishing”, “analyzing”, “checking”, or the like, can refer to operation(s) and/or process(es) of a computer, a computing platform, a computing system, or other electronic computing device, that manipulates and/or transforms data represented as physical (e.g., electronic) quantities within the computer's registers and/or memories into other data similarly represented as physical quantities within the computer's registers and/or memories or other information non-transitory storage medium that can store instructions to perform operations and/or processes.

Although embodiments of the invention are not limited in this regard, the terms “plurality” and “a plurality” as used herein can include, for example, “multiple” or “two or more”. The terms “plurality” or “a plurality” can be used throughout the specification to describe two or more components, devices, elements, units, parameters, or the like. The term set when used herein can include one or more items. Unless explicitly stated, the method embodiments described herein are not constrained to a particular order or sequence. Additionally, some of the described method embodiments or elements thereof can occur or be performed simultaneously, at the same point in time, or concurrently.

1. A method of relaying a wireless power beam using a relay antenna having a plurality of phase shifters, the method comprising:
receiving at the relay antenna, from a first emitter positioned on a transmit antenna at a first location relative to the relay antenna, a first pilot beam directed towards the relay antenna;
receiving at the relay antenna, from a second emitter positioned on a receive antenna at a second location relative to the relay antenna, a second pilot beam;
determining, by the relay antenna, a phase for each phase shifter of the plurality of phase shifters based on a difference in phase between the first pilot beam and the second pilot beam as received by each phase shifter of the relay antenna; and
setting, by the relay antenna, each phase shifter to operate with the respective determined phase to relay a wireless power beam from the transmit antenna to the receive antenna.

2. The method of claim 1, further comprising at each phase shifter adding a phase shift to one of the first or second pilot beams, wherein determining the phase for each phase shifter further comprises determining the phase based on a difference in phase between the phase-shifted first or second pilot beam and the other of the first or second pilot beam.

3. The method of claim 1, further comprising:
receiving at the relay antenna, from the first emitter positioned on the transmit antenna at a first location relative to the relay antenna, a first update pilot beam directed towards the relay antenna;
receiving at the relay antenna, from the second emitter positioned on the receive antenna at a second location relative to the relay antenna, a second update pilot beam;
determining an updated phase for each phase shifter of the plurality of phase shifters based on an updated difference in phase between the first update pilot beam and the second update pilot beam as received by each phase shifter of the relay antenna; and
setting, by the relay antenna, each phase shifter to operate with the respective updated phase.

4. The method of claim 1, further comprising at each phase shifter adding an updated phase shift to one of the first or second pilot beams, wherein determining the updated phase for each phase shifter further comprises determining the updated phase based on a difference in phase between the phase-shifted first or second pilot beam and the other of the first or second pilot beam.

5. A relay antenna for a dual pilot beam for wireless power beaming, the relay antenna comprising:
a plurality of phase shifting element, wherein each phase shifting element comprises:
a phase shifter having a first input for receiving a first pilot beam at a first antenna, said phase shifter configured to output a phase shifted first pilot beam;
a second input for receiving a second pilot beam at a second antenna;
an I Q demodulator to determine a phase difference between the phase shifted first pilot beam and the second pilot beam,
wherein the phase shifting element is configured to set a phase for the particular phase shifter based on the phase difference.

6. The relay antenna of claim 5, wherein the plurality of phase shifting elements are positioned relative to one another with a half-wavelength distance between respective first antennas and respective second antennas of orthogonally adjacent phase shifting elements.

7. A system for a dual pilot beam relay antenna for wireless power beaming, the system comprising:
a relay antenna comprising a plurality of phase shifting elements;
a first emitter positioned at a first location relative to the relay antenna, the first emitter to transmit a first pilot beam;
a second emitter positioned at a second location relative to the relay antenna, the second emitter to transmit a second pilot beam;
wherein the relay antenna is positioned to receive said first and second pilot beams, and
wherein each phase shifting element of the relay antenna is adapted to set a reconfigurable phase shift based on a difference in phase between the first pilot beam and the second pilot beam as received by each respective phase shifting element.

8. The system of claim 7, further comprising at each phase shifting element a phase shifter for adding a phase shift to one of the first or second pilot beams, wherein each phase shifting element of the relay antenna is adapted to set the reconfigurable phase shift based on a difference in phase between the phase-shifted first or second pilot beam and the other of the first or second pilot beam.

9. The system of claim 8, wherein each of the phase shifting elements further comprises an I Q demodulator to determine a phase difference between the phase-shifted first or second pilot beam and the other of the first or second pilot beam.

10. The system of claim 7, wherein the plurality of phase shifting elements are positioned relative to one another with a half-wavelength distance between orthogonally adjacent phase shifting elements.

11. The system of claim 7, wherein N=4A/λ², wherein N is the number of phase shifting elements, A is the overall aperture area of the relay antenna, and λ is the wavelength of the first and second pilot beams.

12. The system of claim 7, wherein the wavelength of the first and second pilot beams is equal to the wavelength of the wireless power beam to be relayed.
